(19) United States
(12) Patent Application Publication
(10) Pub. No.: US 2015/0035410 A1
(43) Pub. Date: Feb. 5, 2015

(54) PIEZOELECTRIC VIBRATING PIECE, METHOD FOR FABRICATING THE PIEZOELECTRIC VIBRATING PIECE, PIEZOELECTRIC DEVICE, AND METHOD FOR FABRICATING THE PIEZOELECTRIC DEVICE

(71) Applicant: NIHON DEMPA KOGYO CO., LTD., Tokyo (JP)

(72) Inventors: SHUICHI MIZUSAWA, SAITAMA (JP); TAKEHIRO TAKAHASHI, SAITAMA (JP)

(21) Appl. No.: 14/337,233

(22) Filed: Jul. 22, 2014

(30) Foreign Application Priority Data
Aug. 5, 2013 (JP) 2013-162262

(51) Int. Cl. H03H 9/17; H01L 41/23; H03H 3/02; H01L 41/107; H01L 41/053

(52) U.S. Cl. CPC H03H 9/17; H01L 41/107; H01L 41/053; H03H 3/02; H01L 41/23
USPC 310/321; 29/25.35

(57) ABSTRACT

A piezoelectric vibrating piece includes a vibrator, a framing portion that surrounds the vibrator, and a connecting portion that connects the vibrator and the framing portion together. At least one of a front surface and a back surface of the connecting portion is formed at a depth of 5 μm to 15 μm with respect to the framing portion.

### CROSS REFERENCE TO RELATED APPLICATIONS

This application claims the priority benefit of Japanese application serial no. 2013-162262, filed on Aug. 5, 2013. The entirety of the above-mentioned patent application is hereby incorporated by reference herein and made a part of specification.

### TECHNICAL FIELD

This disclosure relates to a piezoelectric vibrating piece, a method for fabricating the piezoelectric vibrating piece, a piezoelectric device, and a method for fabricating the piezoelectric device.

### DESCRIPTION OF THE RELATED ART

Electronic equipment such as a mobile terminal and a mobile phone includes a piezoelectric device such as a crystal unit and a crystal oscillator. This piezoelectric device is constituted of a piezoelectric vibrating piece such as a quartz-crystal vibrating piece, a lid, and a base. The piezoelectric vibrating piece includes a vibrator, a framing portion, and a connecting portion. The vibrator vibrates at a predetermined vibration frequency. The framing portion is formed to surround the vibrator. The connecting portion connects the vibrator and the framing portion together. The piezoelectric vibrating piece is formed by, for example, etching an AT-cut quartz-crystal material. In this piezoelectric vibrating piece, the lid is bonded to the front surface of the framing portion via a bonding material. Similarly, the base is bonded to the back surface of the framing portion via the bonding material (see Japanese Unexamined Patent Application Publication No. 2012-147228).

Now, etching of the piezoelectric vibrating piece is generally performed so as to have a mirror finish on the surface. However, the quartz-crystal material may have a lattice defect (disturbance of the atomic arrangement of the quartz crystal). When this quartz-crystal material having the lattice defect is etched, micro-protrusions and micro-depressions (hereinafter referred to as micro-protrusions and similar portion) are formed on the surfaces due to the difference in etching rate. Since a stress is likely to concentrate on these micro-protrusions and similar portion, cracking or similar trouble may occur starting from the micro-protrusions and similar portion. Additionally, the micro-protrusions and similar portion grow and are formed to be large in proportion to the etching amount. Therefore, in the case where large micro-protrusions and similar portion are formed in a portion on which a large stress acts like the connecting portion of the piezoelectric vibrating piece, a problem arises that cracking or damage is likely to occur and then damage to the piezoelectric vibrating piece is caused.

A need thus exists for a piezoelectric vibrating piece, a method for fabricating the piezoelectric vibrating piece, a piezoelectric device, and a method for fabricating the piezoelectric device which are not susceptible to the drawbacks mentioned above.

### SUMMARY

A piezoelectric vibrating piece according to this disclosure includes: a vibrator; a framing portion that surrounds the vibrator; and a connecting portion that connects the vibrator and the framing portion together. At least one of a front surface and a back surface of the connecting portion is formed at a depth of 5 μm to 15 μm with respect to the framing portion.

### BRIEF DESCRIPTION OF THE DRAWINGS

The foregoing and additional features and characteristics of this disclosure will become more apparent from the following detailed description considered with reference to the accompanying drawings.

FIG. 1A is a plan view illustrating a piezoelectric vibrating piece according to a first embodiment.

FIG. 1B is a cross-sectional view taken along the line IB-IB of FIG. 1A.

FIGS. 2A to 2H are diagrams each illustrating a fabrication process of the piezoelectric vibrating piece illustrated in FIGS. 1A and 1B.

FIGS. 3A to 3D are diagrams each illustrating another fabrication process of the piezoelectric vibrating piece illustrated in FIGS. 1A and 1B.

FIG. 4A is a plan view illustrating a piezoelectric vibrating piece according to a second embodiment.

FIG. 4B is a cross-sectional view taken along the line IVB-IVB in FIG. 4A.

FIG. 5 is an exploded perspective view illustrating an embodiment of a piezoelectric device.

FIG. 6 is a flowchart illustrating a fabrication process of the piezoelectric device in FIG. 5.

FIG. 7 is a plan view illustrating a piezoelectric wafer.

FIG. 8 is a plan view illustrating a lid wafer.

FIG. 9 is a plan view illustrating a base wafer.

### DETAILED DESCRIPTION

The following description describes the embodiments of this disclosure with reference to the drawings. This disclosure, however, is not limited to these embodiments. In addition, to describe the following embodiments, the drawings are appropriately scaled, for example, partially enlarged or highlighted. In the drawings, the hatched portion expresses a metal film. In each drawing below, the directions are indicated using the XYZ coordinate system. In this XYZ coordinate system, the XZ plane corresponds to a plane parallel to a front surface of a piezoelectric vibrating piece. In the XZ plane, the X direction corresponds to a longitudinal direction, and the Z direction corresponds to a direction perpendicular to the X direction. The Y direction corresponds to a direction perpendicular to the XZ plane (the thickness direction of the piezoelectric vibrating piece). The explanations are given assuming that a direction indicated by the arrow is the positive direction, and a direction opposite to the direction indicated by the arrow is the negative direction in each of the X direction, the Y direction, and the Z direction.

### Configuration of Piezoelectric Vibrating Piece According to First Embodiment

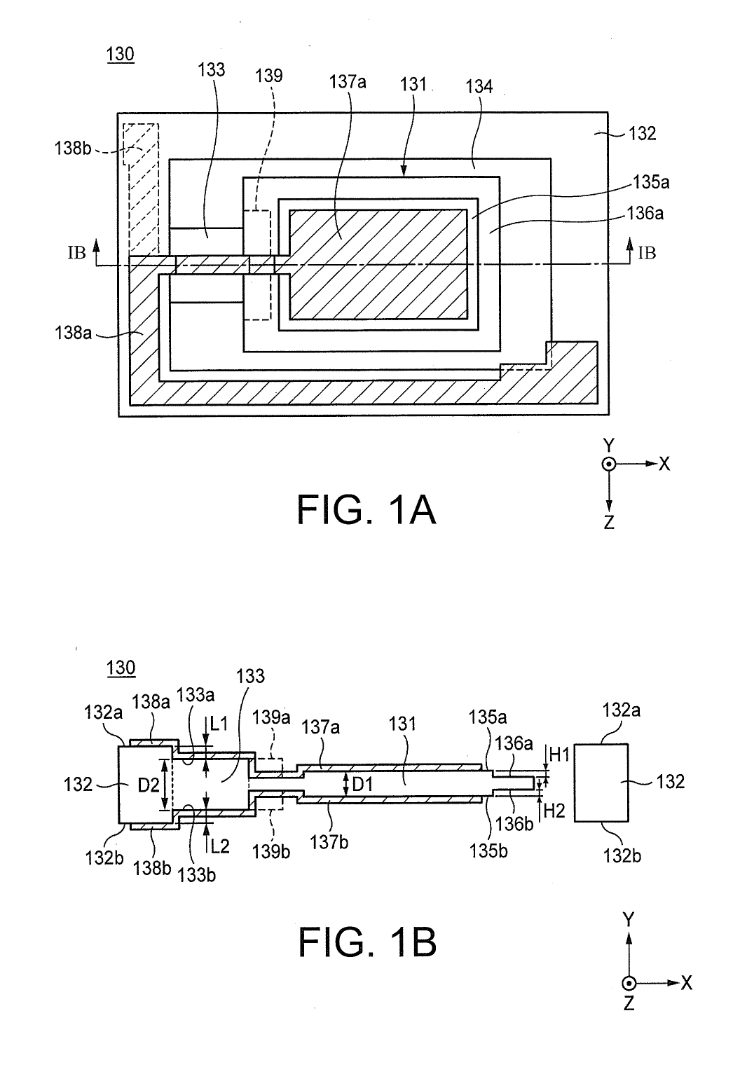

A piezoelectric vibrating piece 130 according to a first embodiment will be described using FIGS. 1A and 1B. As illustrated in FIG. 1A, the piezoelectric vibrating piece 130 includes a vibrator 131 that vibrates at a predetermined vibration frequency, a framing portion 132 that surrounds the vibrator 131, and a connecting portion 133 that connects the vibrator 131 and the framing portion 132 together. Between the vibrator 131 and the framing portion 132, a through-hole 134 is formed. The through-hole 134 passes through the piezoelectric vibrating piece 130 in the Y-axis direction except for the connecting portion 133.

For example, an AT-cut quartz-crystal vibrating piece is used as the piezoelectric vibrating piece 130. An AT-cut method can advantageously obtain excellent frequency characteristics when a piezoelectric device such as a crystal resonator and a crystal oscillator is used at near ordinary temperature. The AT-cut method is a processing method for cutting out a quartz crystal at an angle inclined by 35°15′ around the crystallographic axis with respect to the optical axis of the three crystallographic axes of a synthetic quartz crystal, which are the electrical axis, the mechanical axis, and the optical axis. The same applies to a second embodiment described later.

As illustrated in FIG. 1A, the vibrator 131 is formed in a rectangular shape that has a long side in the X-axis direction and a short side in the Z-axis direction viewing from the Y-axis direction. As illustrated in FIG. 1B, the front surface (the surface on the +Y-side) of the vibrator 131 includes a mesa 135a in the central portion and a mesa peripheral portion 136a that surrounds the mesa 135a. The back surface (the surface on the −Y-side) of the vibrator 131 includes a mesa 135b in the central portion and a mesa peripheral portion 136b that surrounds the mesa 135b. The mesa 135a has a height H1 in the +Y-axis direction with respect to the mesa peripheral portion 136a. The mesa 135b has a height H2 in the −Y-axis direction with respect to the mesa peripheral portion 136b.

By disposing the mesas 135a and 135b in the vibrator 131 as described above, the vibration energy of the piezoelectric vibrating piece 130 is efficiently enclosed (traps), thus reducing the crystal impedance value (CI value). The heights H1 and H2 are formed to be the same as respective depths L1 and L2 of the connecting portion 133 with respect to the framing portion 132 described later. Here, the heights H1 and H2 may be different from the respective depths L1 and L2. Additionally, it is possible to eliminate one or both of the mesas 135a and 135b. The same applies to a vibrator 231 of the second embodiment described later. Additionally, the vibrator 131 has a thickness (the width of the mesa 135a and the mesa 135b in the Y-axis direction) D1 in the Y-axis direction.

The framing portion 132 is formed in a rectangular shape that has a long side in the X-axis direction and a short side in the Z-axis direction as a whole. The framing portion 132 includes a front surface (the surface on the +Y-side) 132a and a back surface (the surface on −Y-side) 132b that are formed as respective surfaces bonded to a bonding surface 112 of a lid 110 and a bonding surface 122 of a base 120, which will be described later.

The connecting portion 133 connects the vibrator 131 and the framing portion 132 together. The connecting portion 133 has respective widths in the X-axis direction and the Z-axis direction viewing from the Y-axis direction, and is formed, for example, in a rectangular shape. The connecting portion 133 includes a front surface (the surface on the +Y-side) 133a formed to have a depth (the distance in the Y-axis direction) L1 with respect to the front surface 132a of the framing portion 132. The connecting portion 133 includes a back surface (the surface on the −Y-side) 133b formed to have a depth (the distance in the Y-axis direction) L2 with respect to the back surface 132b of the framing portion 132. The depths L1 and L2 are both set to 5 μm to 15 μm. The depths L1 and L2 are formed to be the same depth. Here, one of the depths L1 and L2 need not be set to 5 μm to 15 μm. For example, one of the front surface 133a and the back surface 133b may be formed on the same surface of the front surface 132a or the back surface 132b of the framing portion 132.

In the case where the depths L1 and L2 are shallower than 5 μm, it is difficult to block the bonding material from protruding inward. In the case where the depths L1 and L2 are deeper than 15 μm, the number of etchings is increased. Therefore, there remains a possibility that large micro-protrusions and similar portion are formed. The depths L1 and L2 are set to, for example, 10 μm. This achieves a balance between the effect that blocks the protruding bonding material and the effect that reduces growth of the micro-protrusions and similar portion.

The connecting portion 133 is formed thicker than the vibrator 131. The connecting portion 133 has a thickness (the length in the Y-axis direction) D2 formed thicker than a thickness D1 of the vibrator 131. Here, the thickness D2 may be formed to be the same thickness as the thickness D1, or may be formed to be a thickness thinner than the thickness D1.

On the surface of the mesa 135a in the vibrator 131, as illustrated in FIGS. 1A and 1B, an excitation electrode 137a in a rectangular shape is formed. Similarly, on the surface of the mesa 135b, an excitation electrode 137b in a rectangular shape is formed. Application of predetermined A.C. voltages to these excitation electrodes 137a and 137b causes the vibrator 131 to vibrate at a predetermined vibration frequency. Additionally, extraction electrodes 138a and 138b are formed. The extraction electrodes 138a and 138b electrically connect to the respective excitation electrodes 137a and 137b.

The extraction electrode 138a is extracted from the −X-side of the excitation electrode 137a via the surface of the mesa 135a, the surface of the mesa peripheral portion 136a, and the front surface 133a of the connecting portion 133 to the front surface 132a on the −X-side of the framing portion 132. Additionally, the extraction electrode 138a is extended in the +Z direction on the front surface 132a of the framing portion 132 and then folded in the +X direction, and is extracted to the region on the +X-side and the +Z-side on the front surface 132a of the framing portion 132. Additionally, the extraction electrode 138a is extracted via a side surface 132c on the inner side of the framing portion 132 to the region on the +X-side and the +Z-side on the back surface 132b.

The extraction electrode 138b is extracted from the −X-side of the excitation electrode 137a via the surface of the mesa 135b, the surface of the mesa peripheral portion 136b, and the back surface 133b of the connecting portion 133 to the back surface 132b on the −X-side of the framing portion 132. Additionally, the extraction electrode 138b is extended in the −Z direction on the back surface 132b of the framing portion 132 and then extracted to the region on the −X-side and the −Z-side on the back surface 132b. Here, the extraction electrode 138a and the extraction electrode 138b are not electrically connected together.

The excitation electrodes 137a and 137b and the extraction electrodes 138a and 138b are electrically-conductive metal films, and are formed by sputtering, vacuum evaporation, plating, or similar method using a metal mask. This metal film has a two-layered structure which includes a base layer for ensuring adhesion with a quartz-crystal material (the piezoelectric vibrating piece), and a main electrode layer. The base layer includes, for example, a chrome (Cr), a titanium (Ti), a nickel (Ni), an aluminum (Al), a tungsten (W), a nickel-chrome (NiCr) alloy, a nickel-titanium (NiTi) alloy, or a nickel-tungsten (NiW) alloy. The main electrode layer is formed of, for example, a gold (Au) or a silver (Ag). Here, the electrically-conductive metal film is not limited to the above-described configuration, and may have a structure with three or more layers in which, for example, a nickel-tungsten layer is laminated on a chrome layer as the base layer.

As illustrated in FIGS. 1A and 1B, a connected portion 139 with the connecting portion 133 in the vibrator 131 may be formed to have the same thickness as the thickness of the mesa peripheral portions 136a and 136b. The connected portion 139 is not limited to this embodiment. The connected portion 139 may be formed to have the same thickness as the thickness D2 of the connecting portion 133. In this case, a front surface (the surface on the +Y-side) 139a and a back surface (the surface on the −Y-side) 139b of the connected portion 139 are formed to have the same depths as the respective depths L1 and L2 of the connecting portion 133. The front surface 139a of the connected portion 139 is located on the same surface of the front surface 133a of the connecting portion 133. Additionally, the back surface 139b of the connected portion 139 is located on the same surface of the back surface 133b of the connecting portion 133. However, the connected portion 139 may be formed to have a different thickness from the thickness of the mesa peripheral portions 136a and 136b and from the thickness of the connecting portion 133. Alternatively, one of the front surface 139a and the back surface 139b of the connected portion 139 may be formed to have the same depth as the depth L1 or L2.

As illustrated in FIG. 1A, the connected portion 139 is formed to have a wider width in the Z-axis direction than that of the connecting portion 133. The width in the X-axis direction and the width in the Z-axis direction of the connected portion 139 can be set to any widths. For example, the width in the Z-axis direction may be the same as or narrower than the width of the connecting portion 133. The shape of the connected portion 139 viewed from the Y-axis direction is not limited to the rectangular shape, and may be formed in, for example, a semicircle shape, a semi-elliptical shape, an oval-like shape, or a multiangular shape other than a quadrangular shape.

Thus, with the first embodiment, the respective depths L1 and L2 of the connecting portion 133 are set to 5 μm to 15 μm. This prevents the bonding material disposed in the framing portion 132 from flowing into the connecting portion 133 due to the thickness difference between the framing portion 132 and the connecting portion 133. This consequently prevents a change in vibration characteristic of the vibrator 131, thus maintaining the qualities of the piezoelectric vibrating piece 130 and a piezoelectric device 100 described later.

Additionally, setting the respective depths L1 and L2 of the connecting portion 133 to 5 μm to 15 μm keeps the micro-protrusions and similar portion generated on the surface of the connecting portion 133 in small sizes. This allows preventing damage to the piezoelectric vibrating piece 130 due to cracking starting from the micro-protrusions and similar portion or similar trouble. Additionally, the appearance inspection on the connecting portion 133 can be omitted or simplified. This allows reducing the production cost of the piezoelectric vibrating piece 130 or similar device. Additionally, the connecting portion 133 is formed to be thicker than the vibrator 131. This allows ensuring the rigidity of the connecting portion 133, thus improving the durability.

In this embodiment, in the case where the connected portion 139 is formed to have the same thickness as the thickness D2 of the connecting portion 133, this configuration allows reducing growth of the micro-protrusions and similar portion also in this connected portion 139, thus preventing damage to the vibrator 131.

### Method for Fabricating Piezoelectric Vibrating Piece

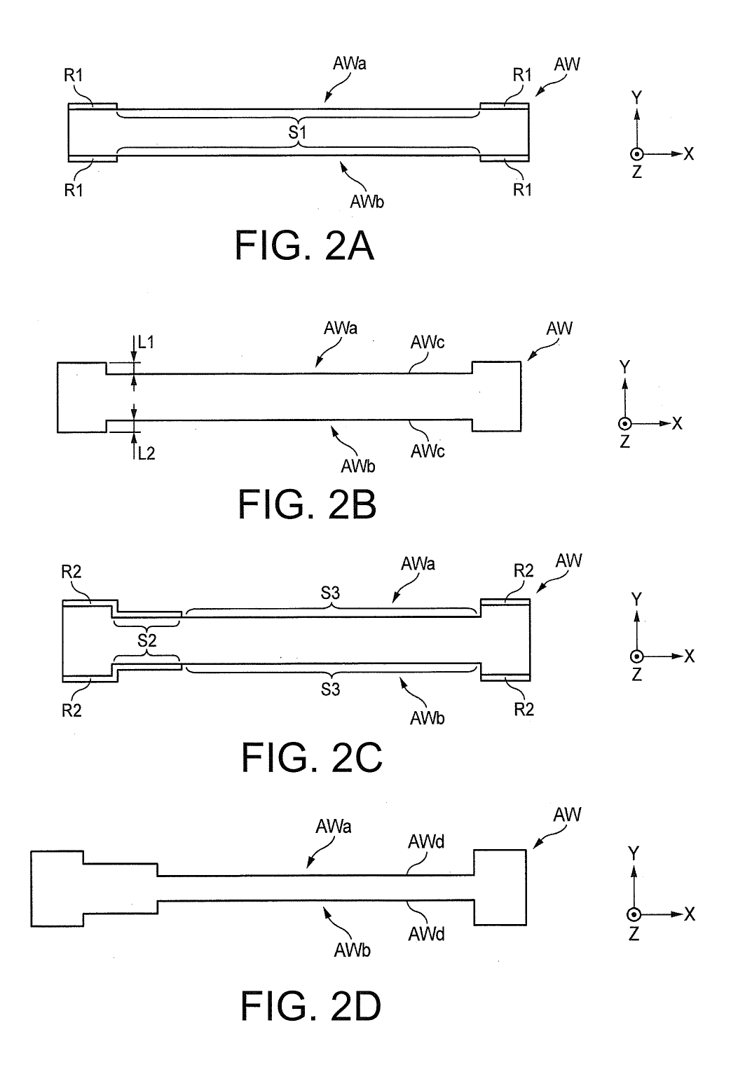

The following description describes a method for fabricating the piezoelectric vibrating piece 130 of this embodiment using FIGS. 2A to 2H. In the fabrication of the piezoelectric vibrating piece 130, a multiple patterning is performed on a piezoelectric wafer (the substrate) AW from which individual pieces are cut out. Here, FIGS. 2A to 2H illustrate fabrication processes in chronological order regarding one of the piezoelectric vibrating pieces 130 formed on the piezoelectric wafer AW. Each diagram illustrated in FIGS. 2A to 2H corresponds to the cross section taken along the line IB-IB in FIG. 1A.

Firstly, as illustrated in FIG. 2A, on the front surface (the surface on the +Y-side) AWa and the back surface (the surface on the −Y-side) AWb of the piezoelectric wafer AW, resist patterns R1 are formed in the regions except regions S1. The piezoelectric wafer AW is finished with a mirrored surface without micro-protrusions and similar portion by polishing or similar method. The piezoelectric wafer AW is cut out from quartz crystal by AT-cut. The piezoelectric wafer AW may be formed to have a predetermined thickness by polishing or similar method. The resist pattern R1 is formed by photolithography. In the photolithography, resist is applied over the front surface AWa and the back surface AWb of the piezoelectric wafer AW. Subsequently, mask patterns are exposed for developing. Here, between the resist pattern R1 and the piezoelectric wafer AW, a mask pattern by a metal film may be formed. Regarding this mask pattern by the metal film, the same applies to the resist pattern described below.

Subsequently, the front surface AWa and the back surface AWb of the piezoelectric wafer AW are etched by wet etching with a predetermined etchant. Accordingly, as illustrated in FIG. 2B, the portions (the regions S1) without being covered with the resist patterns R1 are etched so as to have thinner thicknesses (the widths in the Y-axis direction). Accordingly, on the front surface AWa and the back surface AWb, respective depressed portions AWc with the depths L1 and L2 are formed. Thus, the regions S1 including the connecting portion 133 are each formed as a region at a depth of 5 μm to 15 μm from the surface of the framing portion 132 (in a first process).

Subsequently, as illustrated in FIG. 2C, resist patterns R2 are formed on the front surface AWa and the back surface AWb except regions S3. The resist pattern R2 is formed by photolithography, similarly to the resist pattern R1. In the photolithography, resist is applied over the entire surface of the piezoelectric wafer AW. Subsequently, mask patterns are exposed for developing. The resist patterns R2 are mask patterns for forming the vibrator 131.

Subsequently, the front surface AWa and the back surface AWb of the piezoelectric wafer AW are etched by wet etching with a predetermined etchant. Accordingly, as illustrated in FIG. 2D, the portions (the regions S3) without being covered with the resist patterns R2 are etched so as to have thinner thicknesses. Accordingly, depressed portions AWd are formed in the regions S3. At this time, since the depressed portion AWc is a portion including the vibrator 131, the thickness of the depressed portion AWc is adjusted as necessary such that the vibrator 131 has a desired frequency characteristic. Thus, the regions S3 that excludes the connecting portion 133 and includes the vibrator 131 are thinned (in a second process).

Subsequently, as illustrated in FIG. 2E, resist patterns R3 are formed on the front surface AWa and the back surface AWb except regions S4. The resist pattern R3 is formed by photolithography, similarly to the resist pattern R1. The resist patterns R3 are mask patterns for forming the mesas 135a and 135b.

Subsequently, the front surface AWa and the back surface AWb of the piezoelectric wafer AW are etched by wet etching with a predetermined etchant. Accordingly, as illustrated in FIG. 2F, the portions (the regions S4) without being covered with the resist patterns R3 are etched so as to have thinner thicknesses. Accordingly, on the front surface AWa and the back surface AWb, respective depressed portions AWe with the same depths as the heights H1 and H2 are formed.

Subsequently, as illustrated in FIG. 2G, resist patterns R4 are formed on the front surface AWa and the back surface AWb except regions S5. The resist pattern R4 is formed by photolithography, similarly to the resist pattern R1. The resist patterns R4 are mask patterns for forming the through-hole 134.

Subsequently, the front surface AWa and the back surface AWb of the piezoelectric wafer AW are etched by wet etching with a predetermined etchant. Accordingly, as illustrated in FIG. 2H, the portions (the regions S5) without being covered with the resist patterns R4 are etched so as to form the through-hole 134. As illustrated in FIG. 2H, respective excitation electrodes 137a and 137b and extraction electrodes 138a and 138b are formed on the vibrator 131, the framing portion 132, and the front surface 133a and the back surface 133b of the connecting portion 133. These excitation electrodes 137a and 137b and extraction electrodes 138a and 138b are formed almost at the same time by forming electrically-conductive metal films by sputtering, vacuum evaporation, or similar method using a metal mask. As the metal films, for example, a nickel-tungsten film is formed as the base layer and then a gold film is formed as the main electrode layer. Here, as the base layer, a nickel-tungsten film may be formed after a chrome film is formed. Thus, the piezoelectric vibrating piece 130 is formed. Here, in the piezoelectric vibrating piece 130, in the case where the connected portion 139 is formed to have the same thickness as the thickness of the connecting portion 133, the connected portion 139 is formed together with the connecting portion 133.

Thus, with the method for fabricating the piezoelectric vibrating piece 130, providing the first process and the second process allows forming the connecting portion 133 at the depth of 5 μm to 15 μm from the surface of the framing portion 132, and allows forming the vibrator 131 with a predetermined thickness that provides a desired frequency characteristic. Additionally, in the case where the connected portion 139 is disposed in the piezoelectric vibrating piece 130, only the regions except the connected region with the connecting portion 133 in the regions S3 are thinned in the above-described second process. This allows forming the connected portion 139 with a predetermined thickness.

With the above-described method for fabricating the piezoelectric vibrating piece 130, the first process is performed immediately after the piezoelectric wafer AW is prepared. This allows facilitating the first process, and allows more reliably forming the respective regions S2 including the connecting portion 133 at the depths L1 and L2 of 5 μm to 15 μm.

With the above-described method for fabricating the piezoelectric vibrating piece 130, the second process is performed immediately after the first process. Thus, in the regions S4 including the vibrator 131, the thinning amount in the second process is reduced corresponding to the thinning amount in the first process. That is, the etching amount in the second process is reduced and the etching time is shortened. Thus, the production cost of the piezoelectric vibrating piece 130 can be reduced.

### Another Method for Fabricating Piezoelectric Vibrating Piece

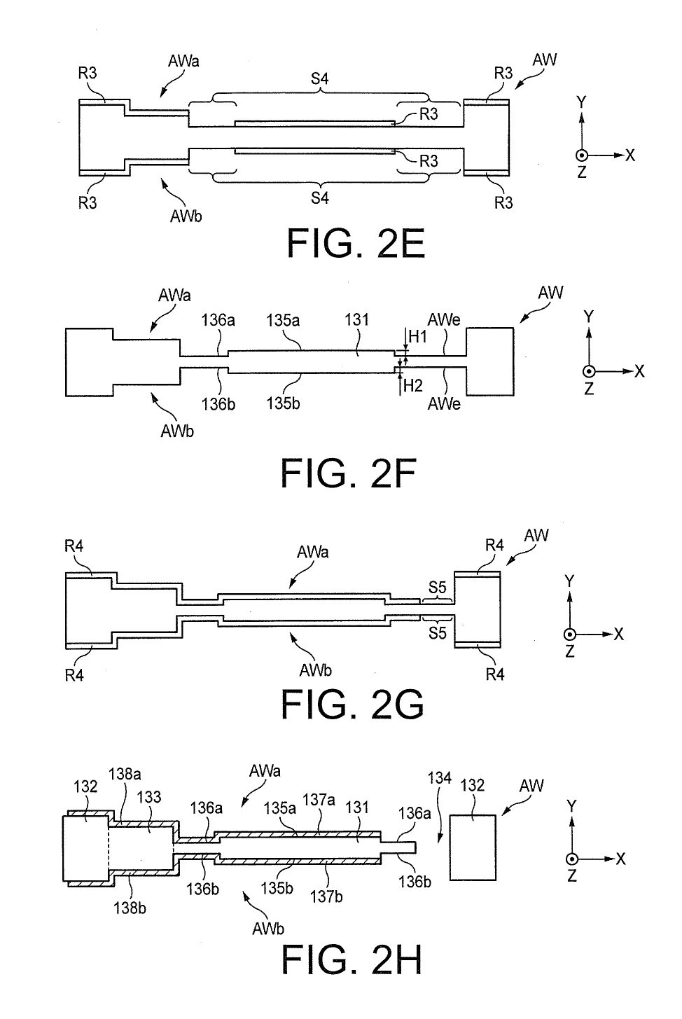

The following description describes another fabrication method that is different from the above-described method for fabricating the piezoelectric vibrating piece 130 using FIGS. 3A to 3D. Each diagram in FIGS. 3A to 3D corresponds to the cross section taken along the line IB-IB in FIG. 1A.

Firstly, as illustrated in FIG. 3A, on the front surface AWa and the back surface AWb of the piezoelectric wafer AW, the resist patterns R5 are formed in the regions except the regions S3. The piezoelectric wafer AW is finished with a mirrored surface without micro-protrusions and similar portion by polishing or similar method. The piezoelectric wafer AW is cut out from quartz crystal by AT-cut. The piezoelectric wafer AW may be formed to have a predetermined thickness by polishing or similar method. The resist pattern R5 is formed by photolithography.

Subsequently, the front surface AWa and the back surface AWb of the piezoelectric wafer AW are etched by wet etching with a predetermined etchant. Accordingly, as illustrated in FIG. 3B, the portions (the regions S3) without being covered with the resist patterns R5 are etched so as to have thinner thicknesses. Accordingly, depressed portions AWd are formed in the regions S3. At this time, since the depressed portion AWc is a portion including the vibrator 131, the thickness of the depressed portion AWc is adjusted as necessary such that the vibrator 131 has a desired frequency characteristic. Thus, the regions S3 that excludes the connecting portion 133 and includes the vibrator 131 are thinned (in the second process).

Subsequently, as illustrated in FIG. 3C, resist patterns R6 are formed on the front surface AWa and the back surface AWb except regions S6 the resist pattern R6 is formed by photolithography. The resist patterns R6 are mask patterns for adjusting the depth of the connecting portion 133 and for forming the mesas 135a and 135b.

Subsequently, the front surface AWa and the back surface AWb of the piezoelectric wafer AW etched by wet etching with a predetermined etchant. Accordingly, as illustrated in FIG. 3D, the portions (the regions S5) without being covered with the resist patterns R6 are etched so as to have thinner thicknesses (the widths in the Y-axis direction). Accordingly, the respective regions of the connecting portion 133 on the front surface AWa and the back surface AWb are formed to have the depths L1 and L2 at depths of 5 μm to 15 μm from the surfaces of the framing portion 132 (in the first process). Simultaneously, on the front surface AWa and the back surface AWb, the respective mesas 135a and 135b with the heights H1 and H2 are formed.

The subsequent processes are similar to the above-described processes illustrated in FIGS. 2G and 2H. On the piezoelectric wafer AW, the through-hole 134 is formed (see FIG. 2G). Subsequently, the respective excitation electrodes 137a and 137b and the respective extraction electrodes 138a and 138b are formed on the vibrator 131, the framing portion 132, and the front surface 133a and the back surface 133b of the connecting portion 133 (see FIG. 2H). Thus, the piezoelectric vibrating piece 130 is formed.

Thus, with the above-described other method for fabricating the piezoelectric vibrating piece 130, the process for forming the mesas 135a and 135b and the first process are simultaneously performed. Additionally, the depths L1 and L2 are the same as the respective heights H1 and H2 in the piezoelectric vibrating piece 130. This simplifies the fabrication process and ensures shortening of the fabrication time for the piezoelectric vibrating piece 130, thus reducing the production cost.

As described above, any one of the first process and the second process can be performed first. However, the method for fabricating the piezoelectric vibrating piece 130 is not limited to the above-described two methods. For example, a part or all of the first process and the second process may be concurrently performed. Here, in the case where the connected portion 139 has the thickness D2 illustrated in FIG. 1B, the connected portion 139 can be formed simultaneously with the process for forming the connecting portion 133 with the depths L1 and L2.

### Second Embodiment

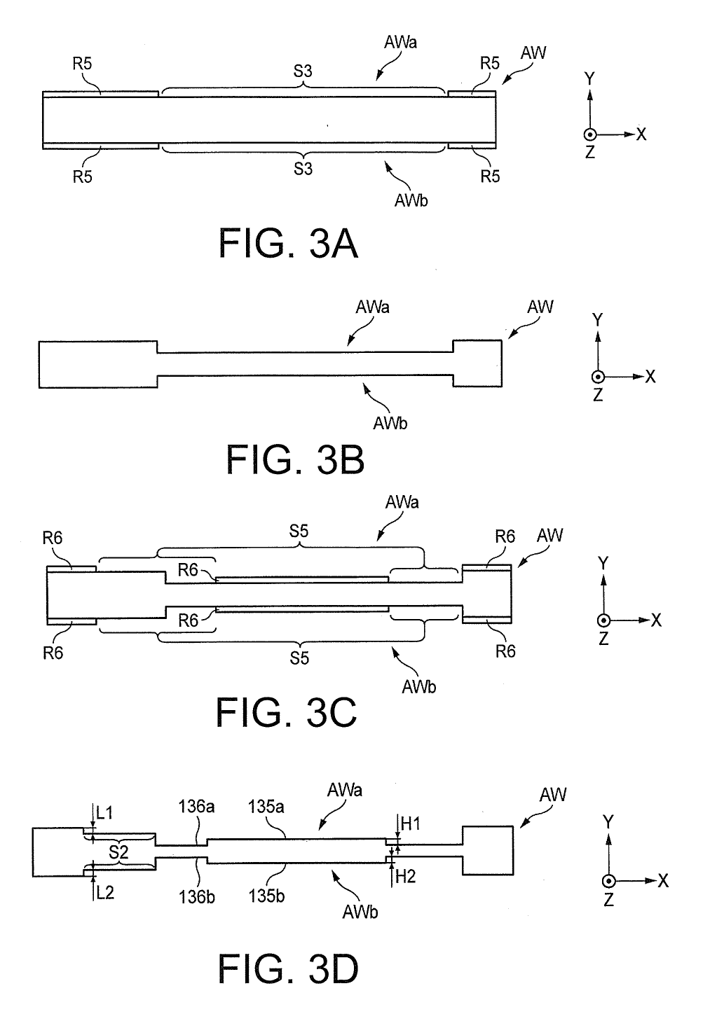

The following description describes a piezoelectric vibrating piece 230 according to a second embodiment using FIGS. 4A and 4B. In the following description, like reference numerals designate identical or corresponding parts of the first embodiment, and therefore such elements will not be further elaborated or simplified here. The piezoelectric vibrating piece 230 according to this embodiment is different from the piezoelectric vibrating piece 130 illustrated in FIGS. 1A and 1B in that a connecting portion 233 is disposed instead of the connecting portion 133 of the first embodiment.

As illustrated in FIGS. 4A and 4B, the piezoelectric vibrating piece 230 includes the connecting portion 233. As illustrated in FIG. 4B, the connecting portion 233 is formed such that the front surface and the back surface of the connecting portion 233 each have the depressed central portion in the Z-axis direction. The +Z-side and the −Z-side of the connecting portion 233 on both sides of the depressed portions are formed to have the same thickness.

The connecting portion 233 connects the vibrator 131 and the framing portion 132 together. In the region including the −Z-side end portion on a front surface 233a of the connecting portion 233, a projecting portion 233c that projects in the +Y-axis direction is disposed. In the region including the +Z-side end portion on the front surface 233a of the connecting portion 233, a projecting portion 233d that projects in the +Y-axis direction is disposed. Additionally, in the region including the −Z-side end portion on a back surface 233b of the connecting portion 233, a projecting portion 233e that projects in the +Y-axis direction is disposed. In the region including the +Z-side end portion on the back surface 233b of the connecting portion 233, a projecting portion 233f that projects in the +Y-axis direction is disposed. In the connecting portion 233, an extraction electrode 238a is formed to pass between the projecting portion 233c and the projecting portion 233d. Additionally, an extraction electrode 238b is formed to pass between the projecting portion 233e and the projecting portion 233f.

The surfaces (the front surface 233a of the connecting portion 233) on the +Y-side of the projecting portion 233c and the projecting portion 233d each have a depth (the distance in the −Y-axis direction) L3 with respect to the front surface 132a of the framing portion 132. Additionally, the surfaces (the back surface 233b of the connecting portion 233) on the −Y-side of the projecting portion 233e and the projecting portion 233f each have a depth (the distance in the −Y-axis direction) L4 with respect to the back surface 132b of the framing portion 132. The depths L3 and L4 are set to 5 μm to 15 μm. While the depth L3 and the depth L4 are formed to be the same depth, the depth L3 and the depth L4 may be different depths. Alternatively, one depth of the depth L3 and the depth L4 may be less than 5 μm or may exceed 15 μm. For example, one of the surfaces on the +Y-side of the projecting portion 233c and the projecting portion 233d and the surfaces on the −Y-side of the projecting portion 233e and the projecting portion 233f may be formed on the same surface of the front surface 132a or the back surface 132b of the framing portion 132.

The connecting portion 233 has a thickness D22 thicker than the thickness D1 (see FIG. 1B) of the vibrator 131. Here, this thickness D22 may be set to the same thickness as the thickness D1 or a thickness thinner than the thickness D1.

Each surface of the projecting portions 233c to 233f is formed in a rectangular shape. Here, a part or all of the projecting portions 233c to 233f may be different in width and shape. Alternatively, a part of the projecting portions 233c to 233f may be eliminated. Alternatively, the projecting portion 233c and the projecting portion 233d may be formed to be partially connected together. Alternatively, the projecting portion 233e and the projecting portion 233f may be formed to be partially connected together.

As illustrated in FIGS. 4A and 4B, while connected portions 239a and 239b with the connecting portion 233 in the vibrator 131 may be formed to have thicknesses similar to the thickness of the mesa peripheral portion 136a, the connected portions 239a and 239b are not limited to this. The connected portions 239a and 239b may be formed to have thicknesses thicker than the thickness of the mesa peripheral portion 136a. In this case, the connected portion 239a is connected to the end portion on the +X-side and the −Z-side of the connecting portion 233. The connected portion 239b is connected to the end portion on the +X-side and the +Z-side of the connecting portion 233. In this case, the thicknesses of the connected portions 239a and 239b are the same as the thickness D22 of the connecting portion 233. The front surfaces (the surfaces in the +Y direction) of the connected portions 239a and 239b are formed on the same surface of the surfaces on the +Y-side of the projecting portions 233c and 233d. The back surfaces (the surfaces in the −Y direction) of the connected portions 239a and 239b are formed similarly to the front surface side.

The respective surfaces of the connected portions 239a and 239b are not necessarily formed on the same surfaces of the front surfaces and the back surfaces of the projecting portions 233c to 233e. The front surfaces and the back surfaces of the connected portions 239a and 239b may be formed in a modified manner where the width in the X-axis direction and the width in the Z-axis direction are widened or narrowed. Alternatively, one of the connected portions 239a and 239b may be formed alone. Alternatively, the connected portions 239a and 239b may be integrally formed.

Thus, the second embodiment increases the thicknesses of the +Z-side and the −Z-side of the connecting portion 233 where large stresses are generated while the depths of the surfaces of the connecting portion 233 are set to 5 μm to 15 μm with respect to the framing portion 132. This efficiently reduces the formation of large micro-protrusions and similar portion in this portion, thus improving the impact resistance property of the piezoelectric vibrating piece 230. Here, a method for fabricating the piezoelectric vibrating piece 230 is approximately similar to the above-described method for fabricating the piezoelectric vibrating piece 130.

### Piezoelectric Device

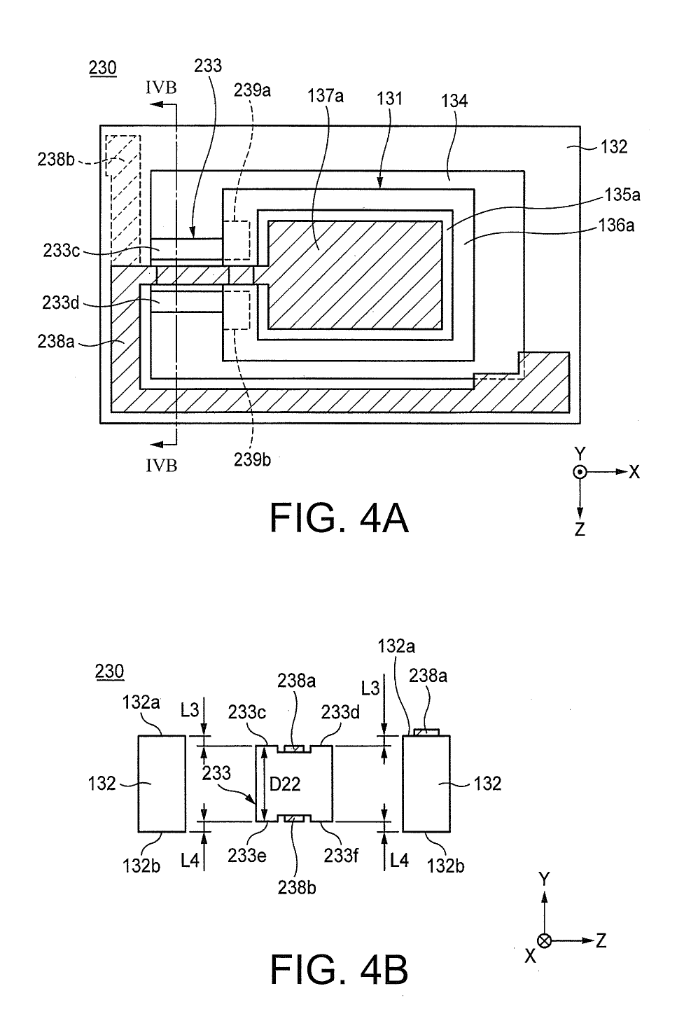

Next, a description will be given of an embodiment of a piezoelectric device. As illustrated in FIG. 5, the piezoelectric device 100 has a configuration where the piezoelectric vibrating piece 130 is sandwiched by the lid 110 and the base 120. The lid 110 is formed at the +Y-side of the piezoelectric vibrating piece 130, and the base 120 is formed at the −Y-side of the piezoelectric vibrating piece 130. The lid 110 and the base 120, similarly to the piezoelectric vibrating piece 130, employ, for example, an AT-cut quartz-crystal material. As the piezoelectric vibrating piece 130, the piezoelectric vibrating piece 130 of the first embodiment illustrated in FIGS. 1A and 1B is employed. Forming the lid 110 and the base 120 with the same materials as that of the piezoelectric vibrating piece 130 avoids the situation where the difference in thermal expansion rate is generated.

As illustrated in FIG. 5, the lid 110 is formed in a rectangular plate shape, and includes a depressed portion 111 formed on the back surface (the surface on the −Y-side) of the lid 110 and the bonding surface 112 that surrounds the depressed portion 111. Here, it is optional whether or not the depressed portion 111 is formed on the back surface of the lid 110. The depressed portion 111 might be unnecessary in the case where the vibrator is thinned with respect to the framing portion 132 similarly to the vibrator 131 of the piezoelectric vibrating piece 130. The bonding surface 112 faces the front surface 132a of the framing portion 132 in the piezoelectric vibrating piece 130.

The lid 110 is bonded to the front surface side (the +Y-side surface side) of the piezoelectric vibrating piece 130 by a bonding material (not illustrated) disposed between the bonding surface 112 and the front surface 132a of the framing portion 132. As the bonding material, for example, low-melting glass, which has non-electrical conductivity, is employed. Instead of this, resins such as polyimide may also be used. Alternatively, the bonding surface 112 and the front surface 132a may be directly bonded together.

As illustrated in FIG. 5, the base 120 is formed in a rectangular plate shape, and includes a depressed portion 121 formed on the front surface (the surface on the +Y-side) of the base 120 and the bonding surface 122 that surrounds the depressed portion 121. The bonding surface 122 faces the back surface 132b of the framing portion 132 in the piezoelectric vibrating piece 130. The base 120 is bonded to the back surface side (the −Y-side surface side) of the piezoelectric vibrating piece 130 by a bonding material (not illustrated) disposed between the bonding surface 122 and the back surface 132b of the framing portion 132. Alternatively, the bonding surface 122 and the back surface 132b may be directly bonded together.

Castellations 123 and 123a, which are partially cutout portions, are formed in two corner portions (a corner portion on the +X-side and +Z-side, and a corner portion on the −X-side and −Z-side) diagonal to each other among four corner portions of the base 120. On the back surface (the surface on the −Y-side) of the base 120, respective external electrodes 126 and 126a are disposed as a mounting terminal pair. At the castellations 123 and 123a, respective castellation electrodes 124 and 124a are formed. Furthermore, on the front surface (+Y-side surface) of the base 120, which is also a region surrounding the castellations 123 and 123a, respective connection electrodes 125 and 125a are formed. These connection electrodes 125 and 125a and the external electrodes 126 and 126a are electrically connected together via the castellation electrodes 124 and 124a. The castellations 123 and 123a are not limited to be disposed at corner portions. The castellations 123 and 123a may be disposed at side portions.

The castellation electrodes 124 and 124a, the connection electrodes 125 and 125a, and the external electrodes 126 and 126a are formed integrally as a conductive metal film, for example, by sputtering or vacuum evaporation using a metal mask. These electrodes may also be separately formed. These electrodes employ, for example, a metal film that has a two-layer structure where a nickel tungsten layer and a gold layer are laminated in this order or a metal film that has a three-layer structure where a chrome layer, a nickel tungsten layer, and a gold layer are laminated in this order.

In the metal film with the three-layer structure, chrome is used for its excellence in adhesion to quartz-crystal materials and to improve a corrosion resistance of a metal film by diffusing to the nickel tungsten layer and forming an oxide film (passivation film) on the exposed surface of the nickel tungsten layer.

As a metal film, for example, aluminum (Al), titanium, or alloy of these materials may be used instead of chrome. Additionally, for example, nickel or tungsten (W) may be used instead of nickel tungsten. Furthermore, for example, silver may be used instead of gold.

The connection electrode 125 of the base 120 is electrically connected to the extraction electrode 138b extracted to the back surface of the piezoelectric vibrating piece 130. The connection electrode 125a is electrically connected to the extraction electrode 138a of the piezoelectric vibrating piece 130. Here, in the base 120, the connection electrodes 125 and 125a are not necessarily connected to the respective external electrodes 126 and 126a by the castellations 123 and 123a. These electrodes may be connected using, for example, through electrodes that pass through the base 120 in the Y-axis direction.

Thus, with the piezoelectric device 100, the piezoelectric vibrating piece 130 with the improved impact resistance property is used. This allows reducing damage to the piezoelectric device 100, thus improving the durability and the reliability of the piezoelectric device 100.

### Method for Fabricating Piezoelectric Device

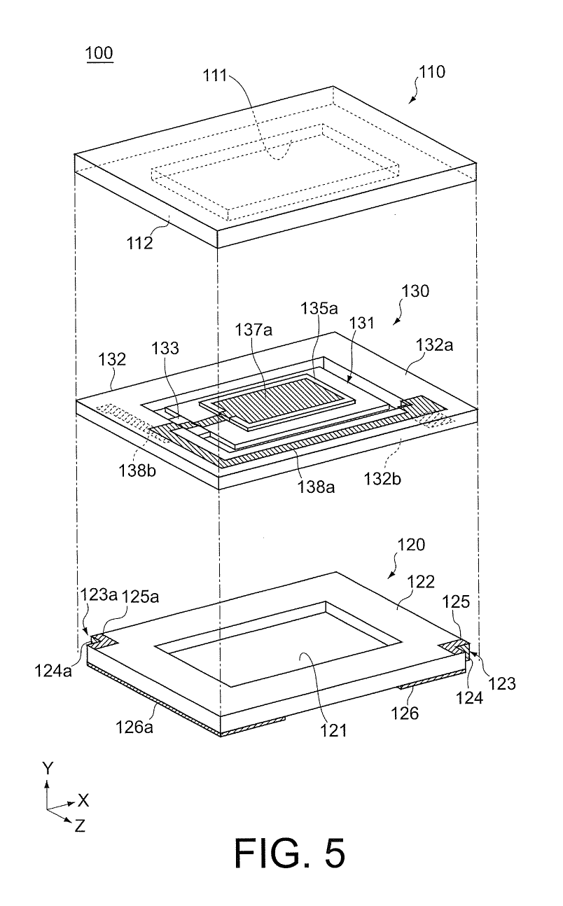

The following description describes a method for fabricating the piezoelectric device 100 using FIG. 6 to FIG. 9. FIG. 6 is a flowchart illustrating a fabrication process of the piezoelectric device 100. Various processes (in the method for fabricating the piezoelectric vibrating piece 130) for the piezoelectric wafer AW are similar to those described above.

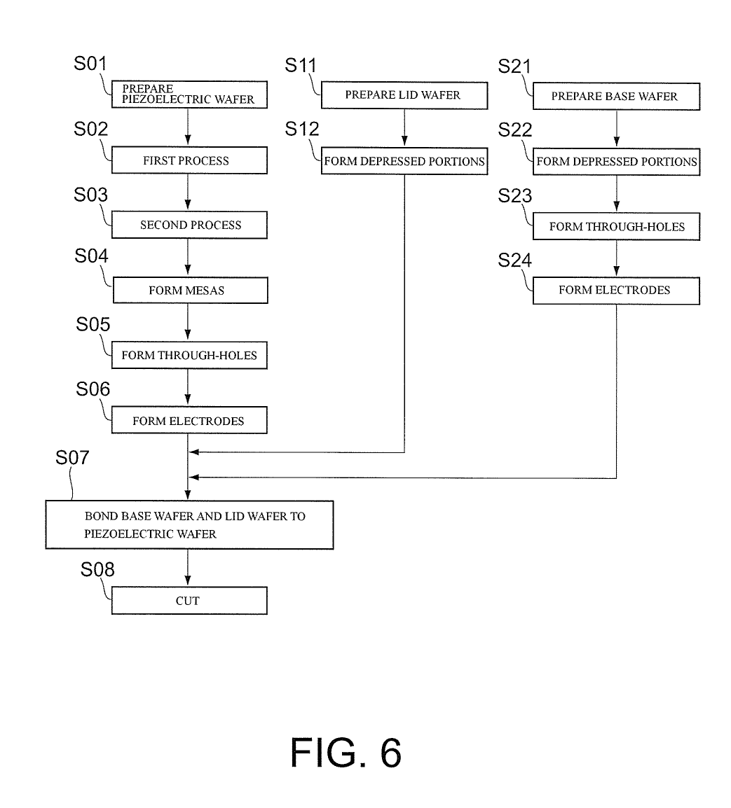

That is, as illustrated in FIG. 6, the piezoelectric wafer AW is prepared (in step S01). Subsequently, the region including the connecting portion 133 on the piezoelectric wafer AW is thinned by the first process (see step S02 and FIG. 2B). Subsequently, the region including the vibrator 131 on the piezoelectric wafer AW is thinned by the second process (see step S03 and FIG. 2C). Subsequently, the mesas 135a and similar portion are formed in the vibrator 131 (see step S04 and FIGS. 2E and 2F). Subsequently, the through-holes 134 are formed on the piezoelectric wafer AW (see step S05 and FIGS. 2G and 2H). Subsequently, the electrodes are formed on the vibrator 131 and similar portion (see step S06 and FIG. 2H). As illustrated in FIG. 7, this results in the formation of the piezoelectric wafer AW on which the configuration members of the piezoelectric vibrating piece 130 are arranged in a matrix. Here, in FIG. 7, the mesa 135a is omitted.

Concurrently with the processing of the piezoelectric wafer AW, the lid 110 and the base 120 are fabricated. For these lid 110 and base 120, multiple individual portions are respectively cut out from the lid wafer LW and the base wafer BW, similarly to the piezoelectric vibrating piece 130.

First, a lid wafer LW and a base wafer BW are prepared along with a piezoelectric wafer AW (in step S11 and step S21). For each wafer, wafers cut out from a quartz crystal by AT cut are used, similarly to the piezoelectric wafer AW. The reason for that is as follows. The manufacturing process of the piezoelectric device 100 includes a process of bonding wafers and a process of forming a metal film on wafer surfaces. In these processes, each wafer is heated and expanded by heat. If wafer materials with different expansion rates are used, difference in expansion rates may cause troubles such as deformation and a crack. Each surface of the wafers LW and BW is polished by polishing and then cleaned.

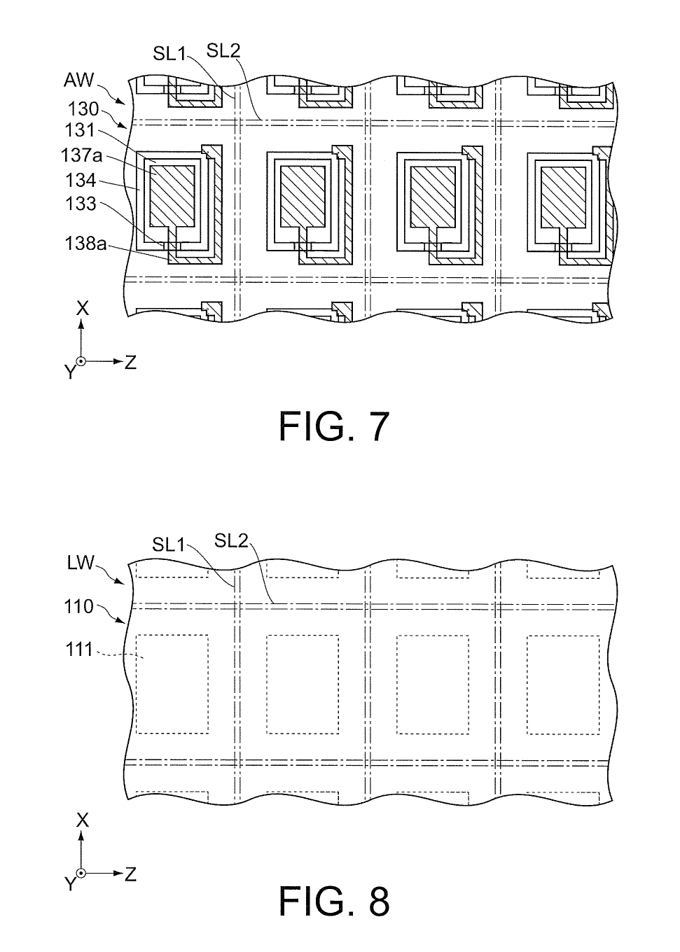

On the lid wafer LW, the depressed portions 111 are formed on the back surface of the lid wafer LW by photolithography and etching (in step S12). As illustrated in FIG. 8, this results in the formation of the lid wafer LW on which the depressed portions 111 are arranged in a matrix. On the front surface of the base wafer BW, the depressed portions 121 are formed by photolithography and etching (in step S22). Subsequently, on the base wafer BW, the through-holes 150 corresponding to the castellations 123 and 123a are formed (in step S23).

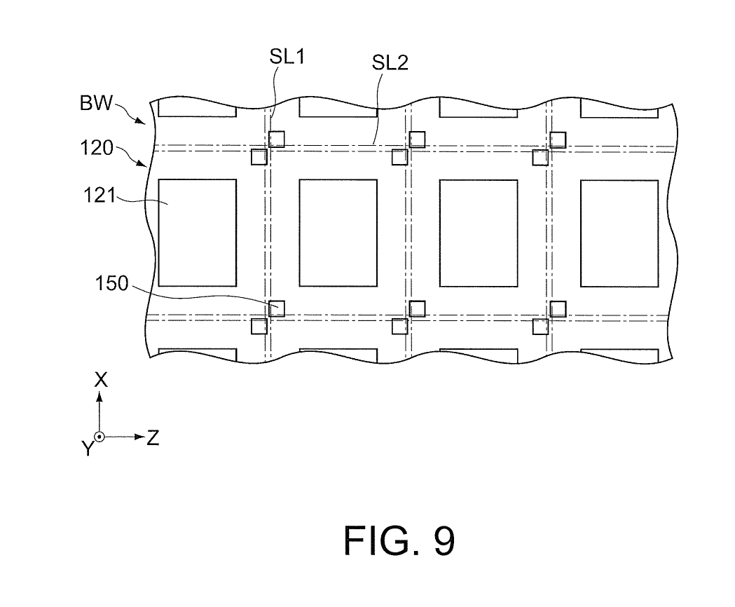

Furthermore, on the base wafer BW, the castellation electrodes are formed on the side surfaces of the through-holes 150. On the front surface side of the base wafer BW, the connection electrodes are formed. On the back surface (the −Y-side surface) side of the base wafer BW, the external electrodes are formed (in step S24). These castellation electrodes, connection electrodes, and external electrodes are each formed by sputtering or vacuum evaporation using a metal mask or similar tool. As illustrated in FIG. 9, this results in the formation of the base wafer BW on which the respective configuration members are arranged in a matrix. Here, in FIG. 9, the illustration of the electrodes is omitted. The processing of the depressed portions 111 and 121 and similar member on the lid wafer LW and the base wafer BW may be performed by a mechanical method instead of etching or similar method.

Subsequently, under vacuum atmosphere, the lid wafer LW illustrated in FIG. 8 is bonded to the front surface of the piezoelectric wafer AW illustrated in FIG. 7 by sandwiching a bonding material while the base wafer BW illustrated in FIG. 9 is also bonded to the back surface of the piezoelectric wafer AW by sandwiching a bonding material (in step S07). The bonding material, which is made of materials such as low-melting glass, is heated and applied in a fused state, and when the bonding material solidifies, it bonds different wafers. Here, the bonding of the lid wafer LW and the base wafer BW to the piezoelectric wafer AW may be direct bonding instead of the bonding with the bonding material.

Subsequently, the bonded wafers are cut along preliminarily designed scribe lines SL1 and SL2 by, for example, a dicing saw (in step S08). Thus, the individual piezoelectric devices 100 are completed.

Thus, the method for fabricating the piezoelectric device 100 allows fabricating the piezoelectric devices 100 in large amounts and in a simple manner, thus providing the above-described piezoelectric device 100 excellent in durability and reliability at low cost. While in the above-described embodiment the piezoelectric vibrating piece 130 described in the first embodiment is used, the piezoelectric vibrating piece 230 described in the second embodiment may be used instead.

While in the above-described embodiment the piezoelectric device 100 employs, for example, the crystal unit (piezoelectric resonator), an oscillator may be employed. For the oscillator, an IC and similar member are mounted on the base 120. The extraction electrode 138a and similar member in the piezoelectric vibrating piece 130 and the external electrodes 126 and 126a in the base 120 are each connected to the IC and similar member. While in the above-described embodiment the lid 110 and the base 120 employ the AT-cut quartz-crystal materials similarly to the piezoelectric vibrating piece 130, another type of quartz-crystal material, glass, ceramic, and similar material may be used instead.

At least one of the front surface and the back surface of the connecting portion may be formed at a depth of 10 μm with respect to the framing portion. The connecting portion may be formed thicker than the vibrator. The vibrator may include a connected portion connected to the connecting portion. The connected portion is formed to have a same thickness as a thickness of the connecting portion. A piezoelectric device may include the above-described piezoelectric vibrating piece.

In a method for fabricating a piezoelectric vibrating piece according to this disclosure, the piezoelectric vibrating piece includes a vibrator, a framing portion that surrounds the vibrator, and a connecting portion that connects the vibrator and the framing portion together. The method includes: a first process, forming a region that includes the connecting portion at a depth of 5 μm to 15 μm from a surface of the framing portion; and a second process, thinning a region that excludes the connecting portion and includes the vibrator. The second process may include thinning the region that includes the vibrator except a connected region connected to the connecting portion.

A method for fabricating a piezoelectric device including the above-described piezoelectric vibrating piece according to this disclosure includes respectively bonding a lid and a base to a front surface and a back surface of the framing portion in the piezoelectric vibrating piece.

This disclosure allows keeping the micro-protrusions and similar portion in small sizes even when the micro-protrusions and similar portion are generated on the front surface and the back surface of the connecting portion. This allows reducing the damage to the piezoelectric vibrating piece due to cracking starting from the micro-protrusions and similar portion or damage even when the connecting portion receives stress, thus improving the durability and the reliability of the piezoelectric vibrating piece and the piezoelectric device. Additionally, the piezoelectric vibrating piece and the piezoelectric device with this feature can be simply and reliably formed.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A piezoelectric vibrating piece, comprising:
a vibrator;
a framing portion that surrounds the vibrator; and
a connecting portion that connects the vibrator and the framing portion together, wherein
at least one of a front surface and a back surface of the connecting portion is formed at a depth of 5 μm to 15 μm with respect to the framing portion.

2. The piezoelectric vibrating piece according to claim 1, wherein
at least one of the front surface and the back surface of the connecting portion is formed at a depth of 10 μm with respect to the framing portion.

3. The piezoelectric vibrating piece according to claim 1, wherein
the connecting portion is formed thicker than the vibrator.

4. The piezoelectric vibrating piece according to claim 1, wherein
the vibrator includes a connected portion connected to the connecting portion,
the connected portion being formed to have a same thickness as a thickness of the connecting portion.

5. A method for fabricating the piezoelectric vibrating piece according to claim 1, the method comprising:
forming a region that includes the connecting portion at a depth of 5 μm to 15 μm from a surface of the framing portion; and
thinning a region that excludes the connecting portion and includes the vibrator.

6. The method for fabricating the piezoelectric vibrating piece according to claim 5, wherein
the step of thinning the region that excludes the connecting portion and includes the vibrator includes:
thinning the region that includes the vibrator except a connected region connected to the connecting portion.

7. A piezoelectric device, comprising:
the piezoelectric vibrating piece according to claim 1.

8. A method for fabricating a piezoelectric device, comprising:
bonding respectively a lid and a base to a front surface and a back surface of the framing portion in the piezoelectric vibrating piece according to claim 1.
